(19) United States
(12) Patent Application Publication
(10) Pub. No.: US 2006/0270113 A1
(43) Pub. Date: Nov. 30, 2006

(54) Method and system for reducing simultaneous switching output noise

(75) Inventors: Yie-Fong Dan, Cupertino, CA (US); Sonny Ngoc Tran, Fremont, CA (US); Raymond Ng, Sunnyvale, CA (US); Betty E. Lee, San Jose, CA (US); Selina Sze Wan Yuen, Milpitas, CA (US)

Correspondence Address: Trellis Intellectual Property Law Group, PC, 1900 EMBARCADERO ROAD, SUITE 109, PALO ALTO, CA, 94303, US

(73) Assignee: Cisco Technology, Inc., San Jose, CA (US)

(21) Appl. No.: 11/138,806

(22) Filed: May 26, 2005

(51) Int. Cl. H01L 21/00

(52) U.S. Cl. 438/118

(57) ABSTRACT

A method and a system for reducing the simultaneous switching output noise in integrated circuit chips. The method includes sending a previous bit pattern and a current bit pattern consecutively on the data bus, wherein the previous bit pattern transitions to the current bit pattern and the number of bits that transition is greater than half the number of bits in the data bus; flipping the current bit pattern to obtain an intermediate bit pattern; sending the intermediate bit pattern; receiving the intermediate bit pattern; and flipping the received intermediate bit pattern, to retrieve the current bit pattern.

### BACKGROUND OF THE INVENTION

1. Field of Invention

Embodiments of the invention relate in general to integrated circuit chips. More specifically, the embodiments of the invention relate to methods and systems for reduction of simultaneous switching output noise on the integrated circuit chips.

2. Description of the Background Art

High-speed applications of integrated circuits are associated with faster switching times. As a result of a high number of outputs that are simultaneously switched, load capacitors discharge, generating transient currents in the process. The transient currents flow through a ground path inductance onto the ground board, developing a voltage across the ground path inductance. The voltage developed across the ground path inductance is inversely related to the change in switching time. Also, the voltage developed across the ground path inductance can be either positive or negative. This voltage results in generation of the simultaneous switching output (SSO) noise. Furthermore, SSO noise increases as a function of small spacing between components on the integrated chip. Reduction in the spacing between the components leads to an increase in the resistive, capacitive, and inductive couplings. Consequently, the voltage rise/drop across these couplings become more significant with the decrease in the spacing between the couplings.

One of the conventional method by which generation of SSO noise can be minimized is by using a large package for housing the integrated circuit chips. A large package is generally characterized by a high number of input output pins. The large size reduces simultaneous switching to a certain extent. However, the large size of the package consumes more board space. In addition, the large package requires more packaging material and therefore higher input costs.

According to another conventional method, which is used to minimize the SSO noise, clock speed of an IC is reduced. However, reducing the clock speed results in lowered performance of the IC.

In yet another conventional method, the SSO noise is minimized by splitting the output of an IC into pin-groups that switch simultaneously. However, this method limits the number of pin-groups that can switch at the same time. This results in a lowered performance of the IC.

### BRIEF DESCRIPTION OF THE DRAWINGS

FIG. 1 illustrates an environment wherein an embodiment of the invention can be practiced.

FIG. 2 illustrates a system for reducing the SSO noise, in accordance with an exemplary embodiment of the present invention.

FIG. 3 illustrates a system for reducing the SSO noise, in accordance with another exemplary embodiment of the present invention.

FIG. 4 illustrates a system for reducing the SSO noise, in accordance with another exemplary embodiment of the present invention.

FIG. 5 illustrates a flow chart depicting a method for reducing switching at the output of a data bus, in accordance with an exemplary embodiment of the present invention.

FIG. 6 illustrates a flow chart depicting another method for reducing switching at the output of the data bus, in accordance with an exemplary embodiment of the invention.

### DETAILED DESCRIPTION OF EMBODIMENTS OF THE INVENTION

The various embodiments of the invention provide a method, a system, and a computer-readable medium for reducing the SSO noise in integrated circuits. The SSO noise is reduced by reducing the number of bits that switch at the output of a data bus. The bits switch when the data bus consecutively outputs two different bit patterns. According to the various embodiments of the invention, the two consecutive bit patterns can be called a previous bit pattern and a current bit pattern. As the name signifies, the previous bit pattern precedes the current bit pattern in the data bus. In one embodiment of the invention, the method comprises flipping all the bits in the current bit pattern if the number of bits that change between the previous bit pattern and the current bit pattern is greater than a pre-determined number. The flipping reduces the number of bits in the pattern that are required to be switched from the previous to the current bit pattern.

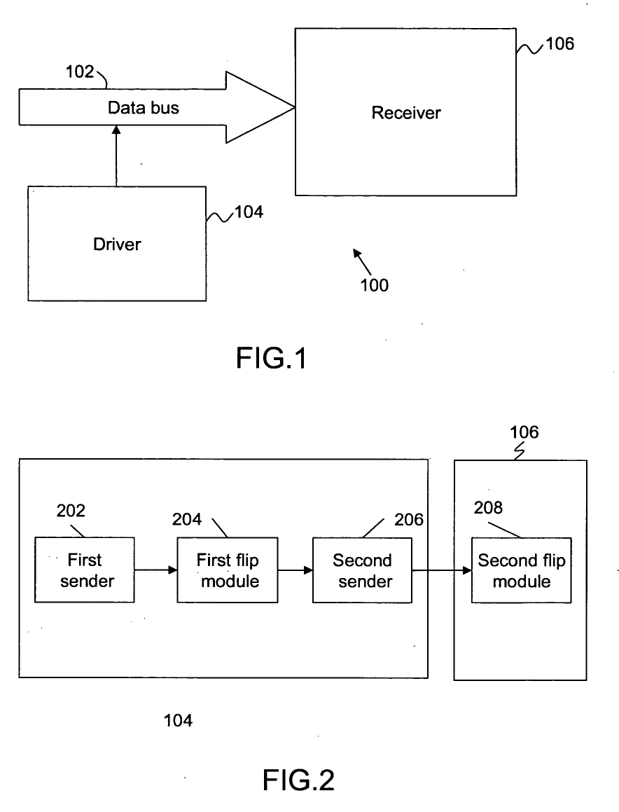

FIG. 1 illustrates an environment 100, in accordance with an exemplary embodiment of the present invention. Environment 100 includes a data bus 102, a driver 104, and a receiver 106. Data bus 102 is controlled by driver 104. Data bus 102 is a collection of wires through which instructions and/or data is transmitted within or to and from a processing unit or a storage device. Each wire is capable of communicating one bit at a time. Examples of data bus 102 include, but are not limited to, an internal data bus, a local data bus, a wide data bus to a memory, and an expansion data bus. The memory includes a Cache Memory, Flash Memory, Random Access Memory, Erasable Programmable Read Only Memory, Non Volatile Random Access Memory etc. According to an exemplary embodiment of the invention, the data is transmitted from a transmitter to a receiver over data bus 102. The data can be in the form of bit patterns.

Driver 104 is a software system that processes the bit patterns that are sent on data bus 102. Driver 104 includes, but is not limited to, a special software interface that interacts with a device, and a program that enables another program to interact with a hardware device. According to various embodiments of the invention, driver 104 may be used for interfacing with printers, video adapters, network cards, sound cards, local buses, low bandwidth I/O buses, hard disk drive, implementing supports for various disk systems, implementing support for digital cameras, and implementing support for image scanners. Driver 104 controls the communication of data from the transmitter to the receiver. Furthermore, driver 104 enables the flipping of the bits in the current bit pattern in order to reduce switching at the output of data bus 102. Receiver 106 receives the data that is sent from the output of data bus 102. Receiver 106 includes, but is not limited to, a device that receives the data and converts the data into useful information in the form of sound, pictures, computer data etc.

FIG. 2 illustrates a system for reducing the SSO noise, in accordance with an exemplary embodiment of the invention. According to the various embodiments of the invention, a first sender 202 sends the bit patterns on data bus 102. In various embodiments of the invention, the two consecutive bit patterns can be called a previous bit pattern and a current bit pattern. In an embodiment of the invention, the previous bit pattern transitions to the current bit pattern such that the number of bits that transition is greater than half the number of bits in the data bus. A first flip module 204 flips all the bits of the current bit pattern into an intermediate bit pattern. During flipping, the state of each bit of the current bit pattern is changed to the opposite state. For example, a current bit pattern 110011 flips to an intermediate bit pattern 001100. According to an exemplary embodiment of the invention, the flipping can be done by using an inverter or a series of NOT gates. A second sender 206 sends the intermediate bit pattern and an additional bit to receiver 106. In an embodiment of the invention, if the additional bit is set, i.e., has logic value ‘1’, then it represents that the number of bits that transition is greater than half the number of bits in data bus 102. A second flip module 208 flips the intermediate bit pattern to obtain the current bit pattern, if the additional bit is set.

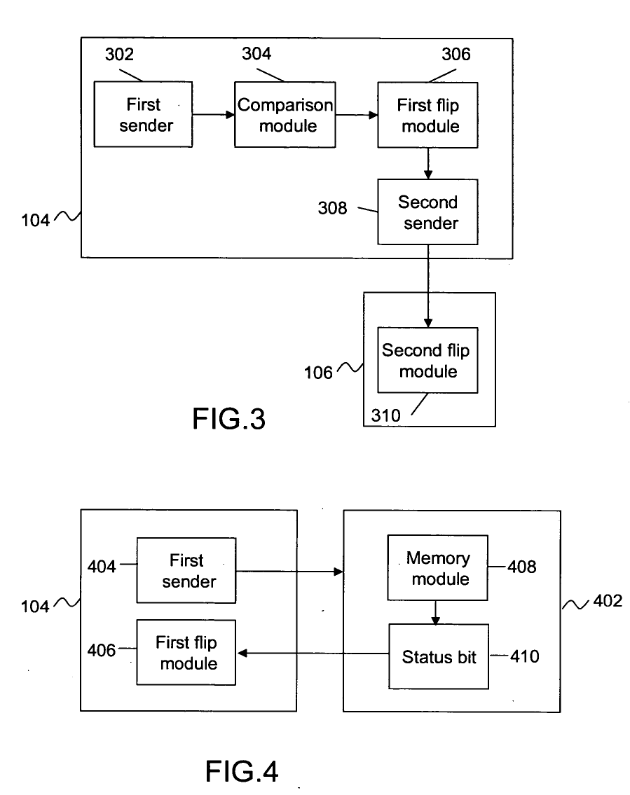

FIG. 3 illustrates a system for reducing the SSO noise, in accordance with another exemplary embodiment of the invention. The driver includes a first sender 302, a comparison module 304, a first flip module 306, a second sender 308, and a second flip module 310. First sender 302 and second sender 308 are similar to first sender 202 and second sender 206. Correspondingly, first flip module 306 is similar to first flip module 204. Comparison module 304 determines the number of bits that transition (N_{b}) between the current bit pattern and the previous bit pattern. The value of N_{b} can be determined by comparing the current bit pattern and the previous bit pattern. Comparison module 304 sends the result of comparison to first flip module 306. The result of comparison is used to determine the value of the additional bit.

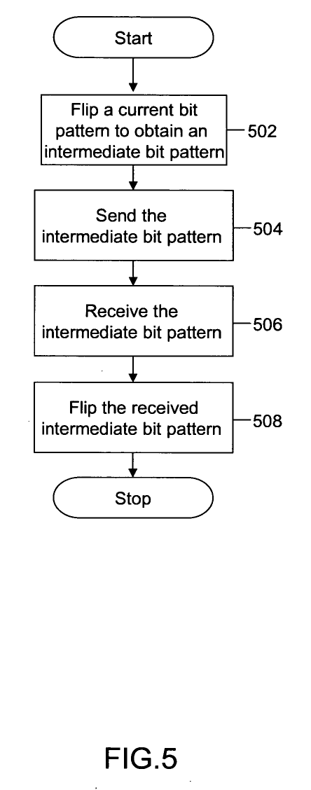

FIG. 4 illustrates a system for reducing the SSO noise, in accordance with another exemplary embodiment of the present invention. The driver includes a first sender 404, and a first flip module 406. In addition, a storage device 402 includes a memory module 408, and a status bit 410. According to various embodiments of the invention, first sender 404 sends the bit patterns to memory module 408. Memory module 408 includes a Cache Memory, Flash Memory, Random Access Memory, Erasable Programmable Read Only Memory, Non Volatile Random Access Memory etc. Status bit 410 represents the bit patterns by an additional bit. In various embodiments of the invention, the additional bit on data bus 102 represents the status of the bit pattern, i.e., whether the bit pattern undergoes more than N/2 transitions or not. In one embodiment of the invention, the first status can be represented by logic value ‘0’, and the second status by logic value ‘1’. In another embodiment of the invention, the first status can be represented by as logic value ‘1’, and the second status by logic value ‘0’. First sender 404 is similar to first sender 202, and first flip module 406 is similar to first flip module 204.

In various embodiments of the invention, the system elements of FIG. 2, FIG. 3, and FIG. 4 can be implemented in the form of software, hardware, firmware, or their combination. The logical operations required for the system elements of FIG. 2 and FIG. 3 can be performed by, but not limited to, resistor-transistor logic, transistor-transistor logic, and Complementary Metal Oxide Semiconductor (CMOS) Logic. In various embodiments of the invention, the Integrated Circuit includes, but is not limited to, Field Programmable Grid Array (FPGA) and Application Specific Integrated Circuit (ASIC). The behavior of FPGA can be determined by using a Hardware Description Language (HDL) or a schematic design using Electronic design automation (EDA) tool. HDL can be a VHSIC Hardware Description Language (VHDL) or a Verilog HDL.

FIG. 5 is a flowchart depicting the requisite steps in reducing the number of switching in the output data bus. At step 502, the current bit pattern is sent on data bus 102. First sender 202 sends the current bit pattern. The previous bit pattern transitions to the current bit pattern. The number of bits that transition can be greater than half the number of bits in data bus 102. At step 502, first flip module 204 flips the current bit pattern to obtain an intermediate bit pattern. The flipping reduces the number of switching required from the previous bit pattern to the intermediate bit pattern at the output of data bus 102. In an embodiment of the invention, the maximum number of bits that can switch at the same time is reduced by half, which reduces the SSO noise by half. At step 504, second sender 206 sends the intermediate bit pattern to receiver 106. At step 506, the intermediate bit pattern is received by receiver 106. At step 508, second flip module 208 flips the received intermediate bit pattern in order to obtain the current bit pattern.

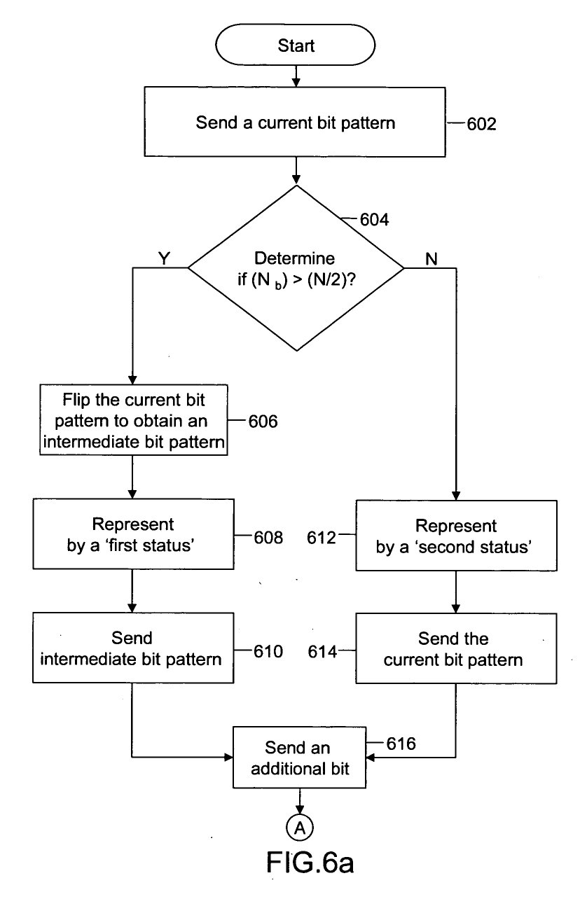

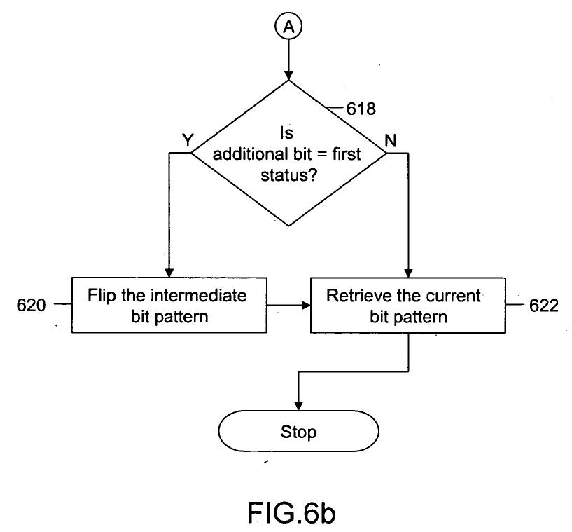

FIG. 6 is a flowchart depicting another method for reducing switching at the output of data bus 102, in accordance with an exemplary embodiment of the invention. At step 602, first sender 302 sends the current bit pattern. At step 604, comparison module 304 determines if the number of bits that transition (N_{b}) between the current bit pattern and the previous bit pattern is more than half the width of the data bus. The total number of data bits that can be carried by the data bus is the width of the data bus. According to the various embodiments of the invention, ‘N’ denotes the width of the data bus. If N_{b} is determined to be greater than half of ‘N’ (N/2) then the method proceeds to step 606. At step 606, first flip module 306 flips the current bit pattern to form the intermediate bit pattern. At step 608, the intermediate bit pattern is represented by a first status. At step 610, second sender 308 sends the intermediate bit pattern and the additional bit to receiver 106.

However, if at step 404 N b is determined to be less than or equal to N, then the method proceeds to step 612. At step 612, the current bit pattern is represented by the second status. At step 614, the current bit pattern is sent to receiver 106. At step 616, the additional bit is sent to receiver 106. The additional bit represents one of the first status and the second status. At step 618, the status of the received bit pattern is determined from the additional bit.

If the additional bit represents the first status, the method proceeds to step 620. At step 620, second flip module 310 flips the received bit pattern. In this case, the received bit pattern is the intermediate bit pattern. Flipping the intermediate bit pattern results in the current bit pattern. In this scenario, the maximum number of bits that can switch at the same time is reduced by half, which reduces the SSO noise by half. At step 622, the current bit pattern is retrieved from receiver 106.

However, if at step 618, the status is determined to be the second status, the method directly proceeds to step 622, i.e., the current bit pattern is retrieved from receiver 106.

In an embodiment of the invention, additional bit is stored in the memory along with the intermediate bit pattern at receiver 106. Subsequently, at the time of reading the intermediate bit pattern, the stored intermediate bit pattern is retrieved after flipping in accordance with method described above.

The above-described method can be further explained in conjunction with the following example. According to an exemplary embodiment of the invention, data bus 102 can be a six bit data bus, i.e., N is equal to six. A current bit pattern 100011 is sent by first sender 302 over data bus 102. A previous bit pattern 011110 transitions to the current bit pattern 100011. In this case, comparison module 304 determines the number of bit transitions (N_{b}) between the current bit pattern 100011 and the previous bit pattern 011110 to be five. Since N_{b} is greater than N/2, first flip module 306 flips the current bit pattern 100011 into an intermediate bit pattern 011100. Therefore, the number of bit transition between the previous bit pattern 011110 and the intermediate bit pattern 011100 is reduced to one. In this case, the intermediate bit pattern 011100 is represented by the first status, for example the additional bit has logic value ‘1’. Second sender 308 sends the intermediate bit pattern and the additional bit representing the first status to receiver 106. Consequently, second flip module 310 retrieves the current bit pattern 100011 by flipping the intermediate bit pattern 011100.

Embodiments of the present invention reduce the SSO noise by conditionally flipping the output data. The maximum number of bits of the output of the data bus that can switch at the same time is reduced by half, which reduces the SSO noise by half. The embodiments of the invention also lead to an improvement in signal integrity. This is done by reducing half of the maximum SSO on any data bus without causing a performance penalty. Furthermore, more output pins can be assigned on an IC package by easing its input output SSO constraint. The power consumption of the IC or a device containing the IC is also reduced as a result of reduced output switching on the data bus. Moreover, the various embodiments of the invention allow device manufacturing and layout at reduced costs by allowing smaller package and die.

Although the invention has been discussed with respect to specific. embodiments thereof, these embodiments are merely illustrative, and not restrictive, of the invention. For example, a ‘method for reducing the switching output noise on the integrated circuit’ can include any type of analysis, manual or automatic, to anticipate the needs of reducing the switching output noise.

Although specific protocols have been used to describe embodiments, other embodiments can use other transmission protocols or standards. Use of the terms ‘peer’, ‘client’, and ‘server’ can include any type of device, operation, or other process. The present invention can operate between any two processes or entities including users, devices, functional systems, or combinations of hardware and software. Peer-to-peer networks and any other networks or systems where the roles of client and server are switched, change dynamically, or are not even present, are within the scope of the invention.

Any suitable programming language can be used to implement the routines of the present invention including C, C++, Java, assembly language, etc. Different programming techniques such as procedural or object oriented can be employed. The routines can execute on a single processing device or multiple processors. Although the steps, operations, or computations may be presented in a specific order, this order may be changed in different embodiments. In some embodiments, multiple steps shown sequentially in this specification can be performed at the same time. The sequence of operations described herein can be interrupted, suspended, or otherwise controlled by another process, such as an operating system, kernel, etc. The routines can operate in an operating system environment or as stand-alone routines occupying all, or a substantial part, of the system processing.

In the description herein for embodiments of the present invention, numerous specific details are provided, such as examples of components and/or methods, to provide a thorough understanding of embodiments of the present invention. One skilled in the relevant art will recognize, however, that an embodiment of the invention can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments of the present invention.

Also in the description herein for embodiments of the present invention, a portion of the disclosure recited in the specification contains material, which is subject to copyright protection. Computer program source code, object code, instructions, text or other functional information that is executable by a machine may be included in an appendix, tables, figures or in other forms. The copyright owner has no objection to the facsimile reproduction of the specification as filed in the Patent and Trademark Office. Otherwise all copyright rights are reserved.

A ‘computer’ for purposes of embodiments of the present invention may include any processor-containing device, such as a mainframe computer, personal computer, laptop, notebook, microcomputer, server, personal data manager or ‘PIM’ (also referred to as a personal information manager), smart cellular or other phone, so-called smart card, set-top box, or any of the like. A ‘computer program’ may include any suitable locally or remotely executable program or sequence of coded instructions, which are to be inserted into a computer, well known to those skilled in the art. Stated more specifically, a computer program includes an organized list of instructions that, when executed, causes the computer to behave in a predetermined manner. A computer program contains a list of ingredients (called variables) and a list of directions (called statements) that tell the computer what to do with the variables. The variables may represent numeric data, text, audio or graphical images. If a computer is employed for presenting media via a suitable directly or indirectly coupled input/output (I/O) device, the computer would have suitable instructions for allowing a user to input or output (e.g., present) program code and/or data information respectively in accordance with the embodiments of the present invention.

A ‘computer readable medium’ for purposes of embodiments of the present invention may be any medium that can contain, store, communicate, propagate, or transport the computer program for use by or in connection with the instruction execution system apparatus, system or device. The computer readable medium can be, by way of example only but not by limitation, an electronic, magnetic, optical, electromagnetic, infrared, or semiconductor system, apparatus, system, device, propagation medium, or computer memory.

Reference throughout this specification to “one embodiment”, “an embodiment”, or “a specific embodiment” means that a particular feature, structure, or characteristic described in connection with the embodiment is included in at least one embodiment of the present invention and not necessarily in all embodiments. Thus, respective appearances of the phrases “in one embodiment”, “in an embodiment”, or “in a specific embodiment” in various places throughout this specification are not necessarily referring to the same embodiment. Furthermore, the particular features, structures, or characteristics of any specific embodiment of the present invention may be combined in any suitable manner with one or more other embodiments. It is to be understood that other variations and modifications of the embodiments of the present invention described and illustrated herein are possible in light of the teachings herein and are to be considered as part of the spirit and scope of the present invention.

Further, at least some of the components of an embodiment of the invention may be implemented by using a programmed general-purpose digital computer, by using application specific integrated circuits, programmable logic devices, or field programmable gate arrays, or by using a network of interconnected components and circuits. Connections may be wired, wireless, by modem, and the like.

It will also be appreciated that one or more of the elements depicted in the drawings/figures can also be implemented in a more separated or integrated manner, or even removed or rendered as inoperable in certain cases, as is useful in accordance with a particular application.

Additionally, any signal arrows in the drawings/Figures should be considered only as exemplary, and not limiting, unless otherwise specifically noted. Combinations of components or steps will also be considered as being noted, where terminology is foreseen as rendering the ability to separate or combine is unclear.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

The foregoing description of illustrated embodiments of the present invention, including what is described in the abstract, is not intended to be exhaustive or to limit the invention to the precise forms disclosed herein. While specific embodiments of, and examples for, the invention are described herein for illustrative purposes only, various equivalent modifications are possible within the spirit and scope of the present invention, as those skilled in the relevant art will recognize and appreciate. As indicated, these modifications may be made to the present invention in light of the foregoing description of illustrated embodiments of the present invention and are to be included. within the spirit and scope of the present invention.

Thus, while the present invention has been described herein with reference to particular embodiments thereof, a latitude of modification, various changes and substitutions are intended in the foregoing disclosures, and it will be appreciated that in some instances some features of embodiments of the invention will be employed without a corresponding use of other features without departing from the scope and spirit of the invention as set forth. Therefore, many modifications may be made to adapt a particular situation or material to the essential scope and spirit of the present invention. It is intended that the invention not be limited to the particular terms used in following claims and/or to the particular embodiment disclosed as the best mode contemplated for carrying out this invention, but that the invention will include any and all embodiments and equivalents falling within the scope of the appended claims.

What is claimed is:

1. A method for reducing switching at the output of a data bus, the method comprising
flipping a current bit pattern to obtain an intermediate bit pattern , wherein a previous bit pattern transitions to the current bit pattern and the number of bits that transition is greater than half the number of bits on the data bus;
sending the intermediate bit pattern;
receiving the intermediate bit pattern; and
flipping the received intermediate bit pattern, to retrieve the current bit pattern.

2. The method of claim 1, wherein the sending further comprises sending an additional bit, the additional bit representing that the number of bits that transition is greater than half the number of bits on the data bus.

3. A method for reducing switching at the output of a data bus, the method comprising
sending a current bit pattern, wherein a previous bit pattern transitions to the current bit pattern;
determining a number of bits that transition from the previous bit pattern to the current bit pattern;
if the number of bits that transition is greater than half the number of bits in the data bus,
then
flipping the current bit pattern to obtain an intermediate bit pattern;
representing the intermediate bit pattern by a first status;
sending the intermediate bit pattern to a receiver; else
representing the current bit pattern by a second status;
sending the current bit pattern to the receiver;
sending an additional bit to the receiver, the additional bit representing one of the first status and the second status; and
if the additional bit represents the first status, then
flipping the intermediate bit pattern to retrieve the current bit pattern;
else
retrieving the current bit pattern.

4. An apparatus for reducing the switching at the output of a data bus, the apparatus comprising:
a first sender, the first sender sending a current bit pattern on the data bus, wherein a previous bit pattern transitions to the current bit pattern and the number of bits that transition is greater than half the number of bits on the data bus;
a first flip module, the first flip module flipping the current bit pattern to obtain an intermediate bit pattern;
a second sender, the second sender sending the intermediate bit pattern; and
a receiver, the receiver receiving the intermediate bit pattern, the receiver comprising
a second flip module, the second flip module flipping the received intermediate bit pattern to retrieve the current bit pattern.

5. The apparatus of claim 4, wherein the apparatus further comprises an additional bit module, the additional bit module representing that the number of bits that transition is greater than half the number of bits in the data bus.

6. An apparatus for reducing the switching at the output of a data bus, the apparatus comprising:
a first sender for sending a current bit pattern on the data bus, wherein a previous bit pattern transitions to the current bit pattern;
a comparison module for determining a number of bits that transition from the previous bit pattern to the current bit pattern;
a first flip module, wherein the first flip module flips the current bit pattern to obtain an intermediate bit pattern if the number of bits that transition are greater than half the number of bits in the data bus, and sends the intermediate bit pattern as an output, and the first flipping module sends the current bit pattern as the output if the number of bits that transition is less than or equal to the number of bits in the data bus;
a second sender for sending the output of the first flip module; and
a receiver, the receiver receiving the output from the second sender, the receiver comprising
a second flip module, wherein the second flip module provides a final output by flipping the output if the output is the intermediate bit pattern, and the second flip module provides the final output as the output if the output is the current bit pattern.

7. A system of reducing the switching at the output of a data bus, the system comprising:
means for sending a current bit pattern on the data bus, wherein a previous bit pattern transitions to the current bit pattern and the number of bits that transition is greater than half the number of bits on the data bus;
means for flipping the current bit pattern to obtain an intermediate bit pattern, the flipping reducing the switching from the previous bit pattern to the intermediate bit pattern at the output of the data bus;
means for sending the intermediate bit pattern;
means for receiving the intermediate bit pattern; and
means for flipping the received intermediate bit pattern to retrieve the current bit pattern.

8. The system of claim 7, wherein means for sending further comprises sending an additional bit, the additional bit representing that the number of bits that transition is greater than half the number of bits in the data bus.

9. A system of reducing the switching at the output of a data bus, the system comprising:
a first means for sending a current bit pattern on the data bus, wherein a previous bit pattern transitions to the current bit pattern;
means for determining a number of bits that transition from the previous bit pattern to the current bit pattern;
a first means for flipping, the first means for flipping flips the current bit pattern to obtain an intermediate bit pattern if the number of bits that transition are greater than half the number of bits in the data bus, and sends the intermediate bit pattern as an output, and, wherein the first means for flipping sends the current bit pattern as the output if the number of bits that transition is less than or equal to the number of bits in the data bus;
a second means for sending the output of the first means for flipping; and
a means for receiving the output from the second sender, the means for receiving comprising a second means for flipping, the second means for flipping flips the output sent by the second means for sending, wherein the second means of flipping provides a final output by flipping the output if the output is the intermediate bit pattern, and the second means for flipping provides the final output as the output if the output is the current bit pattern.

10. An apparatus for reducing the switching at the output of a data bus, the apparatus comprising a processing system including a processor coupled to a display and user input device; a machine-readable medium including instructions executable by the processor comprising one or more instructions for sending a current bit pattern on the data bus, wherein a previous bit pattern transitions to the current bit pattern and the number of bits that transition is greater than half the number of bits on the data bus;
one or more instructions for flipping the current bit pattern to obtain an intermediate bit pattern;
one or more instructions for sending the intermediate bit pattern;
one or more instructions for receiving the intermediate bit pattern; and
one or more instructions for flipping the received intermediate bit pattern.
